(19) United States
(12) Patent Application Publication
(10) Pub. No.: US 2009/0114265 A1
(43) Pub. Date: May 7, 2009

(54) Solar Concentrator

(75) Inventors: Michael Milbourne, Los Altos, CA (US); Hing Wah Chan, San Jose, CA (US); Jason Ellsworth, Mesa, AZ (US); Darrel Bailey, Gilbert, AZ (US); Gill Shook, Santa Cruz, CA (US); Eric Prather, Santa Clara, CA (US)

Correspondence Address: THE MUELLER LAW OFFICE, P.C., 12951 Harwick Lane, San Diego, CA, 92130, US

(73) Assignee: SOLFOCUS, INC., Mountain View, CA (US)

(21) Appl. No.: 12/175,456

(22) Filed: Jul. 18, 2008

Related U.S. Application Data
(63) Continuation-in-part of application No. 12/044,939, filed on Mar. 8, 2008.
(60) Provisional application No. 60/985,215, filed on Nov. 3, 2007.
(60) Provisional application No. 61/016,314, filed on Dec. 21, 2007.

(51) Int. Cl. H01L 31/052; H01L 31/18

(52) U.S. Cl. 136/246; 427/123; 29/825

(57) ABSTRACT

The present invention is an improved solar concentrator array utilizing a monolithic array of primary mirrors with a metal layer deposited on its backside for electrical purposes and for dissipating heat. The array of primary mirrors may be formed by glass slumping. The size of the primary mirrors is chosen to accommodate design aspects related to performance, manufacturing processes, cost, and thermal management. An electrical package, which in one embodiment is a molded leadframe, provides the electrical circuitry between a solar cell and the metal layer. The electrical package may be configured with features such as an aperture or side edges to enhance manufacturability of the solar concentrator array. An array of secondary mirrors may be integrally formed with a front panel of the solar concentrator.

### RELATED APPLICATIONS

This application is a continuation-in-part of the following: (1) U.S. patent application Ser. No. 12/044,939 filed on Mar. 8, 2008, entitled “Monolithic Glass Array,” which claims priority to U.S. Provisional Patent Application Ser. No. 60/985,215 filed on Nov. 3, 2007, entitled “Monolithic Mirror Array”; and (2) U.S. Provisional Patent Application Ser. No. 61/016,314 filed on Dec. 21, 2007, entitled “Leadframe Receiver Package for Solar Concentrator,” all of which are hereby incorporated by reference as if set forth in full in this application for all purposes.

### BACKGROUND OF THE INVENTION

Solar concentrators are solar energy generators which increase the efficiency of converting solar energy into DC electricity. Solar concentrators known in the art utilize, for example, parabolic mirrors and Fresnel lenses for focusing incoming solar energy. Another type of solar concentrator, disclosed in U.S. Patent Publication No. 2006/0266408, entitled “Concentrator Solar Photovoltaic Array with Compact Tailored Imaging Power Units,” utilizes a front panel for allowing solar energy to enter the assembly, with a primary mirror and a secondary mirror to reflect and focus solar energy through a non-imaging concentrator onto a solar cell. The surface area of the solar cell in such a concentrator system is much smaller than what is required for non-concentrating systems, for example less than 1% of the entry window surface area. Such a system has a high efficiency in converting solar energy to electricity due to the focused intensity of sunlight, and also reduces cost due to the decreased surface area of costly photovoltaic cells.

A similar type of solar concentrator is disclosed in U.S. Patent Publication No. 2006/0207650, entitled “Multi-Junction Solar Cells with an Aplanatic Imaging System and Coupled Non-Imaging Light Concentrator.” The solar concentrator design disclosed in this application uses a solid optic, out of which a primary mirror is formed on its bottom surface and a secondary mirror is formed in its upper surface. Solar radiation enters the upper surface of the solid optic, reflects from the primary mirror surface to the secondary mirror surface, and then enters a non-imaging concentrator which outputs the light onto a photovoltaic solar cell.

Many factors, contribute to the commercial success of solar concentrators, such as manufacturing cost, optical performance, and reliability. Manufacturing cost itself is affected by other aspects, such as material costs, the number of components required for assembly, manufacturing tolerances, and processing efficiencies. Opportunities to make improvements in these various areas are continually being sought in the field of solar energy production.

### SUMMARY OF THE INVENTION

The present invention is a solar concentrator array utilizing a monolithic array of primary mirrors with a metal layer deposited on its backside for electrical purposes and for dissipating heat. In one embodiment, the array of primary mirrors may be formed by glass slumping. The size of the primary mirrors is chosen to accommodate design aspects related to performance, manufacturing processes, cost, and thermal management. An electrical package, which in one embodiment is a molded leadframe, provides the electrical circuitry between a solar cell and the metal layer. The electrical package may be configured with features such as an aperture or side edges to enhance manufacturability of the solar concentrator array. Further optional features of the invention include a non-imaging concentrator and an array of secondary mirrors integrally formed with a front panel of the solar concentrator.

### BRIEF DESCRIPTION OF THE DRAWINGS

Reference now will be made in detail to embodiments of the disclosed invention, one or more examples of which are illustrated in the accompanying drawings wherein:

FIG. 1 is a cross-sectional view of an exemplary solar concentrator unit of the present invention;

FIG. 2 depicts a perspective view of exemplary primary mirrors and receiver assemblies;

FIG. 3A shows a cross-sectional view of edges of individually-formed mirrors;

FIG. 3B is a cross-sectional view of an edge of monolithically slumped primary mirrors;

FIG. 3C shows the view of FIG. 3B with the addition of an optional extended edge;

FIG. 4A illustrates a partial cross-sectional view of an embodiment of mirror layers with an electrical package;

FIG. 4B is a partial cross-sectional view of a further embodiment of mirror layers with an electrical package;

FIG. 5A provides a perspective view of an exemplary leadframe package;

FIG. 5B shows a perspective view of an alternative embodiment of a leadframe package;

FIG. 6 is a cross-sectional view of an exemplary receiver assembly with a non-imaging concentrator and heat shield;

FIG. 7 shows an alternative embodiment of an electrical package;

FIG. 8A depicts an exemplary metal layer pattern on the backside of a primary mirror array;

FIG. 8B shows the primary mirror array of FIG. 8A with electrical packages inserted; and

FIG. 9 is an exemplary flowchart for fabricating a solar concentrator array of the present invention.

### DETAILED DESCRIPTION OF THE EMBODIMENTS

FIG. 1 depicts a simplified cross-sectional view of an exemplary embodiment of the solar concentrator of the present invention. A solar concentrator unit 100 includes a front panel 110, a primary mirror 120 with a central opening 125, a secondary mirror 130, an optional non-imaging concentrator 140, and a receiver assembly 150 which incorporates a solar cell 160 and an electrical package 170. A metal layer 180 is deposited on the backside of primary mirror 120 for electrical and thermal purposes. An optional backpan 190 may be used to provide support for and protection for an array of solar concentrator units 100, as well as to provide heat dissipation. In the operation of this embodiment, solar radiation enters solar concentrator unit 100 through front panel 110 and reflects off of primary mirror 120 to secondary mirror 130. Secondary mirror 130 then reflects the radiation to non-imaging concentrator 140 which transmits the light to solar cell 160 for conversion to electrical energy. Note that while a non-imaging concentrator 140 in the form of a truncated prism is depicted in FIG. 1, other optical elements may be utilized instead of or in addition to non-imaging concentrator 140.

Metal layer 180 serves as an electrical conduit for solar concentrator unit 100 and may also provide heat dissipation for solar cell 160. Metal layer 180 may be electrically coupled to electrical package 170 with an electrically conductive substance 181 such as conductive adhesives, metallic solders, or the like. Thus, metal layer 180 advantageously enables electrical package 170 to form an electrical circuit with metal layer 180 in a way which minimizes or eliminates the use of physical wiring. In a further embodiment, metal layer 180 significantly reduces or eliminates the need for separate heat sinking components as well as any associated thermal interface materials. The size of primary mirror 120 is chosen to enable metal layer 180 to provide a portion of the heat dissipation from solar concentrator unit 100, while balancing other design factors affected by mirror size such as optical performance, cost, and manufacturability. As shall be described subsequently in more detail, the solar concentrator of the present invention utilizes a primary mirror 120 having a maximal size within certain limits to enable potentially incompatible processes and components to be integrated into a system yielding improved design and manufacturing benefits.

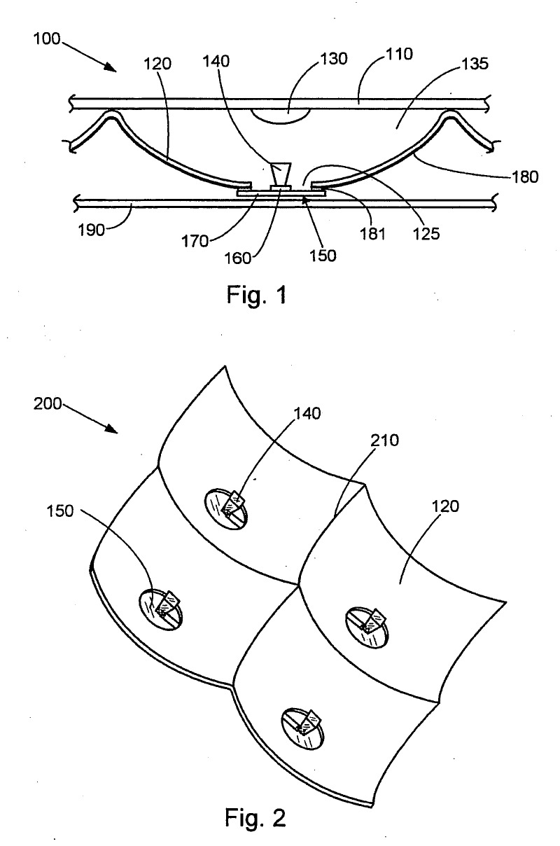

FIG. 2 provides a perspective view of an exemplary array 200 of primary mirrors 120 with non-imaging concentrators 140 and receiver assemblies 150. In this embodiment, primary mirrors 120 have curvatures tailored to achieve a desired focal point, and are monolithically integrated at edges 210. While primary mirrors 120 are shown in FIG. 2 as having square perimeters, they may have other shapes such as hexagonal or circular. The array of primary mirrors 120 is monolithically formed, such as by glass slumping, which improves the cost and manufacturability of primary mirrors 120. For slumping of glass sheets on the order of one square foot or more, the slumping process may utilize multiple vacuum ports within and outside of the cavities of the mold used to form the mirrors as described in U.S. patent application Ser. No. 12/044,939 entitled “Monolithic Glass Array.” Forming a monolithic array allows for multiple primary mirrors 120 to be formed simultaneously, reducing the number of components and inherently aligning them properly with respect to each other. Thus, the time required for manufacturing and assembling primary mirrors 120 is decreased, which reduces cost. Pre-set alignment of primary mirrors 120 may also remove the need for backpan 190 to assist in alignment of components, such as with individually formed primary mirrors. Instead, the tolerances to which backpan 190 is fabricated can be widened, and the need for alignment features within backpan 190 may be reduced or eliminated, thus reducing the cost of backpan 190. In another aspect, having primary mirrors 120 formed from a sheet of glass, with air filling the space between primary mirrors 120 and secondary mirrors 130 rather than a solid optic design where the space between primary mirrors 120 and secondary mirrors 130 is filled with a dielectric, creates a lighter weight array, particularly for larger mirror sizes. A lighter weight array is advantageous in many ways, including easing of handling issues during manufacturing, reducing shipping costs, and decreasing the strength requirements of the tracking structure used to support the array.

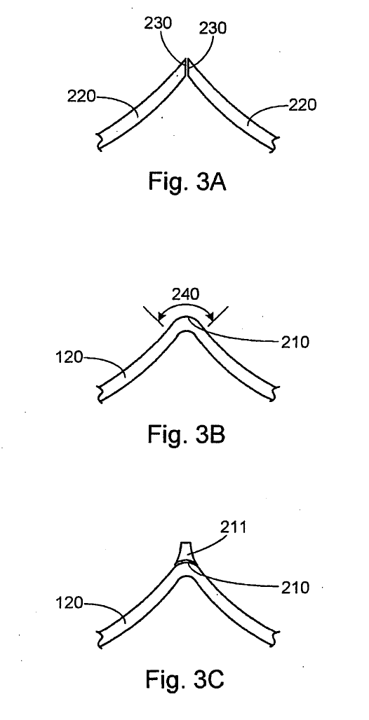

In determining the desired size of a solar concentrator unit 100, certain parameters may drive the design toward a larger size. In one aspect, a monolithic array of mirrors may require certain considerations not present with individually formed mirrors. As shown in the partial cross-sectional view of FIG. 3A, individually-formed primary mirrors 220, which are typically formed as circular mirrors and then cut to the desired shape, maintain a desired mirror curvature at all points up to their cut edges 230. In contrast, the partial cross-sectional view of FIG. 3B shows that primary mirrors 120 slumped monolithically in an array are inherently rounded at the edges 210 by nature of the slumping process. These rounded edges 210 result in optical losses for a solar concentrator system since light reflected at edges 210 will not be concentrated at the desired focal point. With the radius of curvature of edges 210 minimally being twice the glass thickness, the subsequent loss in surface area, designated by the arrow 240, caused by the rounding at edges 210 is greater than or equal to twice the glass thickness multiplied by the total linear measurement of the shared edges 210 and the outer periphery of the array 200. Thus, for a given overall size of array 200, the larger the size of individual primary mirror 120, the less the optical rounding loss. Although rounding losses could be reduced by using thinner glass sheets, the mirrors would become more fragile. FIG. 3C depicts an alternative embodiment of the slumped edges 210, in which extended edges 211 may be added to reduce rounding losses. Extended edges 211 may be, for example, integrally formed with primary mirrors 120 by performing a secondary glass-forming operation on edges 210. In a further embodiment, extended edges 211 may take the form of a separate component mounted onto edges 210.

In another aspect related to performance, designing primary mirrors 120 toward a larger size can facilitate the incorporation of a non-imaging concentrator 140 or other desired optical element into the system. Non-imaging concentrator 140 beneficially increases the acceptance angle of solar concentrator unit 100 by supplying a larger surface area than solar cell 160 upon which light can be received. If the size of primary mirror 120 is too small, there will be insufficient height for housing a non-imaging concentrator 140. Furthermore, the hollow primary mirror 120 of the present invention provides easier assembly for accommodating a non-imaging concentrator 140 than with a solid optic design. For a solid optic, the use of a non-imaging concentrator or other optical element requires that element to be optically coupled to the solid optic to avoid losses at the interface between the two components. This may require adding manufacturing processes, such as applying an encapsulant between the solid optic and the non-imaging concentrator.

Another factor driving the solar concentrator design of the present invention toward larger mirror sizes is cost. The cost of receiver assembly 150, with its solar cell 160 and electrical package 170, can contribute a significant portion of the overall cost of a solar concentrator. The addition of a non-imaging concentrator 140 or other optical element with each receiver assembly 150 can augment this cost even further. Therefore, larger primary mirrors 120, within constraints of other design considerations, enables fewer receiver assemblies 150 to be required per area, which reduces costs of the overall array through decreasing the number of parts and associated assembly steps. Furthermore, larger mirrors may lead to other components in the system being proportionally scaled up in size, which can allow general manufacturing tolerances to be wider than with smaller components.

However, while optical rounding losses and factors associated with the receiver assembly 150 and non-imaging concentrator 140 can influence the design of a monolithically formed array toward larger mirrors, these considerations may require a balance with other factors which are more beneficial for smaller mirrors. In particular, thermal management of a solar concentrator is heavily affected by its size. Typically, smaller primary mirrors 120 result in lower heat loads per solar concentrator unit 100, and consequently allow for more manageable heat dissipation. However, as stated previously, metal layer 180 of the present invention can serve as a means for conducting heat away from solar cell 160 in conjunction with electrical package 170 and backpan 190. Although a larger primary mirror 120 provides a greater surface area for metal layer 180, the commensurate increase in heat generated by the additional mirror surface area is likely to be more than what can be dissipated by typical metal deposition thicknesses, which may be on the order of hundreds of microns. Thus in the present invention, the size of the primary mirror 120 is chosen according to the heat dissipation requirements from the electrical package 170, the metal layer 180, and optional backpan 190. In one embodiment, square primary mirrors 120 may have sides measuring in the range of, for instance, 30 to 300 mm. The desirable size will be determined by balancing factors including the conductivity and thickness of metal layer 180, the heat flux received by the solar concentrator unit 100, and the previously described performance and cost factors which influence the design toward a larger size.

The size of primary mirror 120 may also be limited by processes used to coat the mirror array 200 with the necessary mirror layers and with metal layer 180. For a given mirror curvature, larger mirrors will have a greater depth and consequently be more difficult to coat as an array. Wet chemistry processes may result in pooling in the valleys between the primary mirrors 120 as the depth of the mirrors increases. Vacuum deposition processes such as plasma vapor deposition may offer improved control over the coating process, yet may still result in difficulty in evenly coating the valleys between the primary mirrors 120 as the depth of the mirrors increases. Acceptable coating uniformity may be achieved by choosing a primary mirror size within the process capabilities of the desired coating process.

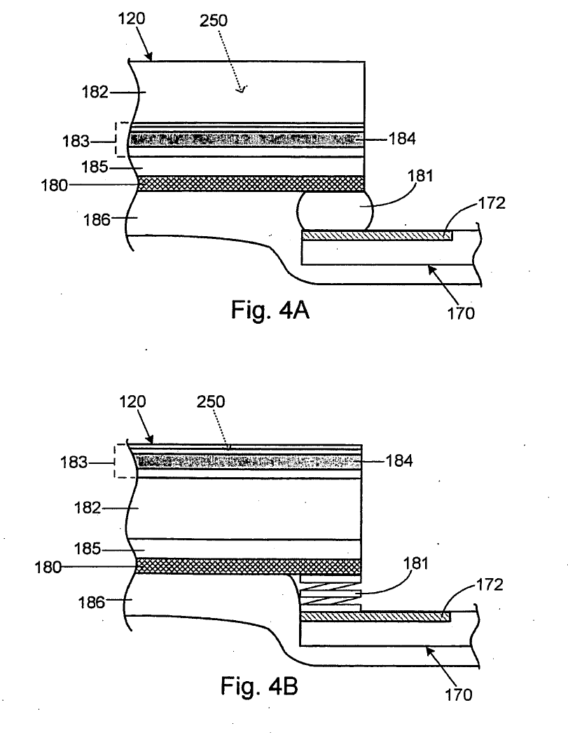

The coating layers for primary mirror 120, including metal layer 180, shall be now described in more detail. FIG. 4A, not drawn to scale, represents a partial cross-sectional view of a primary mirror 120 exemplified as a second surface mirror, coupled with an electrical package 170. Light rays 250 enter the glass substrate 182 and reflect off of mirror structure 183. Mirror structure 183 includes a reflective material 184 such as silver, and also may include various adhesion and enhancement layers known in the art such as silicon nitrides and metal oxides. An optional isolation layer 185, which may be one or more of a paint layer or a polymer substance, may be applied to protect mirror structure 183 against physical damage and to electrically isolate mirror structure 183 from metal layer 180. Metal layer 180 may be, for instance, aluminum or copper, and may be deposited by various processes including, but not limited to, physical vapor deposition, electrolytic plating, electroless plating, and thermal spraying.

Electrical package 170 includes an electrical element 172, which in FIG. 4A is embodied to be coupled to metal layer 180 through an electrically conductive substance 181, such as a silver impregnated adhesive. Electrically conductive substance 181 is also thermally conductive, and may be a substance such as conductive adhesives, metallic solders, welds, ultrasonic bonds, or micro-springs. Electrically conductive substance 181 provides a stand-off to accommodate thermal mismatch between electrical package 170 and primary mirror 120. The ability to mount and electrically connect electrical package 170 to metal layer 180 with electrically conductive substance 181 provides a faster and easier attachment method than using wires and interconnects. Alternatively, there are benefits to reducing wire lengths and interconnects when such connections are still required with this configuration. Heat generated from solar cell 160 (not shown in this figure) is dissipated through electrical package 170, electrically conductive substance 181, metal layer 180, and optionally to backpan 190 if used. The amount of heat capable of being dissipated by metal layer 180 is largely determined by the thickness and surface area of metal layer 180, which is directly related to the size of primary mirror 120. Finally, a polymer layer 186 may be applied, such as a powder coat by spray coating, to provide electrical insulation for metal layer 180.

Polymer layer 186 may additionally provide a conformal coating for hermetically sealing primary mirror 120 with electrical package 170 and front panel 110 (FIG. 1) to prevent condensation from damaging components. In embodiments where the backpan 190 of FIG. 1 is utilized to enclose the solar concentrator array, hermetic sealing may alternatively be achieved through means such as sealants, gaskets, adhesives, and the like between side walls (not shown) of backpan 190 and front panel 110. In other embodiments, the solar concentrator array may be vented, such as with vent holes in backpan 190, instead of hermetically sealing the system.

FIG. 4B is similar to FIG. 4A, but represents primary mirror 120 as a first surface mirror. In this alternative embodiment, light rays 250 reflect off of mirror structure 183 which is applied on top of glass substrate 182. Additionally, FIG. 4B illustrates the use of a micro-spring as an electrically conductive substance 181 for coupling electrical package 170 to metal layer 180. As with FIG. 4A, various combinations of enhancement, adhesion, and protection layers may be incorporated into mirror structure 183 to improve light transmission properties and durability of the mirror structure 183. On the backside of glass substrate 182, an optional isolation layer 185 is depicted. Metal layer 180, electrical package 170, electrically conductive substance 181, and polymer layer 186 complete the assembly as described in relation to FIG. 4A.

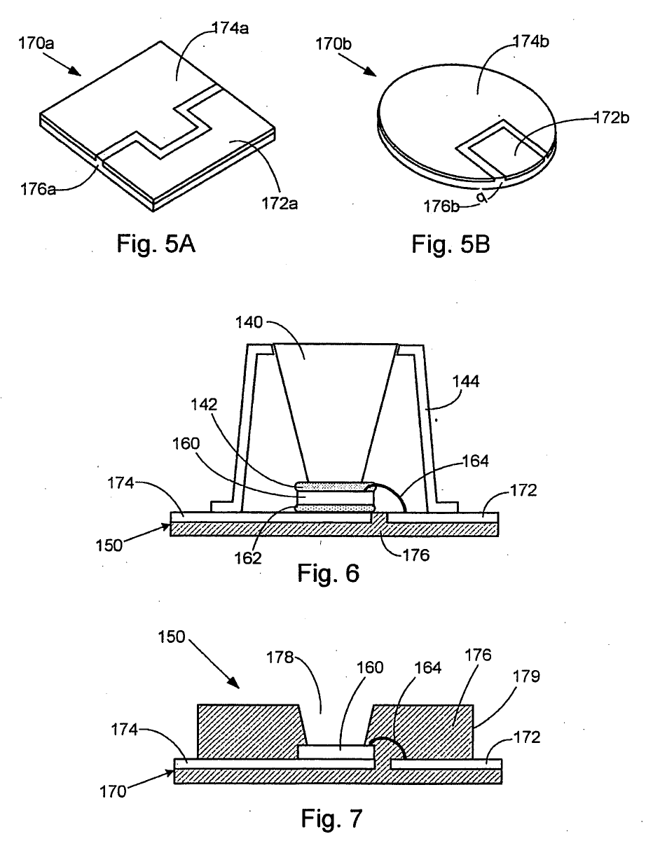

Electrical package 170 may be, for example, a single or multi-layer ceramic package, or a leadframe design. In FIG. 5A, an exemplary leadframe package 170a of the present invention is provided. In this perspective view, leadframe package 170a is a molded leadframe of rectilinear shape. Leadframe package 170a includes a first leadframe element 172a and a second leadframe element 174a which are co-molded together with a molded substrate 176a, such as an epoxy molding compound. Leadframe elements 172a and 174a provide circuitry for connecting solar cell 160 to the power system of the solar concentrator array, and may be made of, for example, nickel-coated copper. Leadframe package 170a is preferably made of materials with coefficients of thermal expansion that are compatible with the type of glass used for primary mirror 120. Note that for the purposes of this description, first and second leadframe elements 172a and 174a are interchangeable, as either may represent a cathode or an anode, and either one may be larger or smaller provided that solar cell 160 can be positioned primarily on one of the leadframe elements 172a or 174a. FIG. 5B illustrates a further embodiment of a leadframe package 170b having a circular shape, with a first leadframe element 172b and a second leadframe element 174b having an alternative layout compared to leadframe elements 172a and 172b of FIG. 5A.

The desired configurations of the electrical packages 170a and 170b in FIGS. 5A and 5B, respectively, may take other forms. For instance, the portions occupied by leadframe elements 172a and 174a (or 172b and 174b) may be altered to accommodate the desired circuitry for a particular design. In another embodiment, fins on the outer edges of leadframe packages 170a or 170b may be added to increase heat dissipation. Furthermore, while it is preferable that solar cell 160 be substantially centered on electrical package 170 for ease of manufacturing, it is possible for a solar concentrator to have solar cell 160 be off-center with respect to electrical package 170.

FIG. 6 shows a cross-sectional view of an exemplary receiver assembly 150 along with associated components. Solar cell 160, which is typically configured with electrical contacts on its top and bottom surfaces, may be mounted to an electrical element 174 of electrical package 170 with a coupling material 162 such as solder, die attach, or similar methods. Coupling material 162 electrically connects the bottom electrical contact of solar cell 160 to electrical element 174 of electrical package 170. The top electrical contact of solar cell 160 may be coupled to electrical element 172 with wire bonds 164 or other electrical coupling known in the art. Solar cell 160 may include a bus bar (not shown) around its perimeter to enable multiple wire bonds 164 to be located all on one edge of solar cell 160. If a non-imaging concentrator 140 is used, an encapsulant 142 can be applied over solar cell 160 to mount non-imaging concentrator 140. An optional heat shield 144 may be placed around non-imaging concentrator 140 and secured by, for example, soldering, bonding, or fastening holes in electrical package 170.

An alternative embodiment of receiver assembly 150 is shown in FIG. 7. In this cross-sectional view, solar cell 160 is incorporated into electrical package 170, with a substrate 176, such as ceramic or an epoxy molding compound, covering portions of the upper surfaces of electrical elements 172 and 174. Solar cell 160 is electrically connected to electrical elements 172 and 174 during fabrication of electrical package 170. In this embodiment of FIG. 7, an aperture 178 is formed during the fabrication of electrical package 170. Aperture 178 may provide alignment and support for non-imaging concentrator 140 or other optical element, not shown in this figure for clarity, or alternatively the walls of aperture 178 may be coated to serve as a light guide. Side faces 179 of substrate 176 may be configured to assist in aligning electrical package 170 over central opening 125 of primary mirror 120.

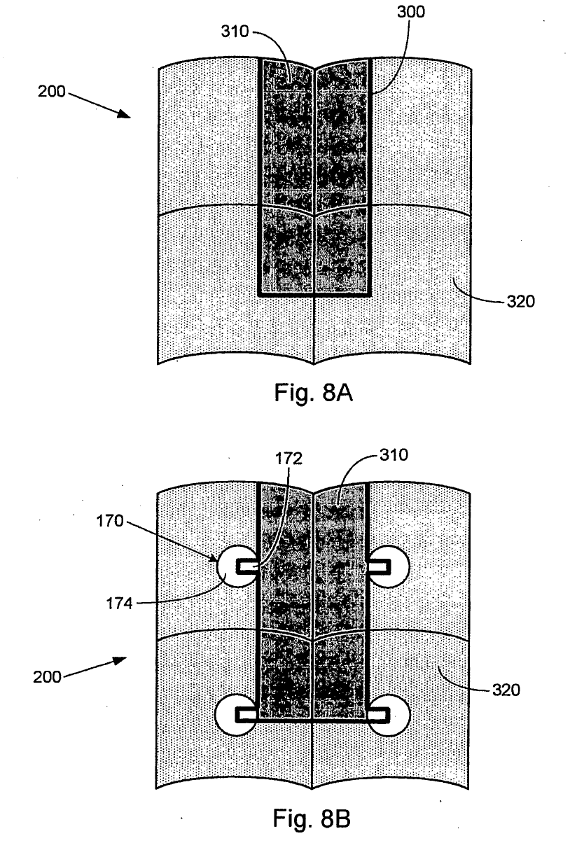

FIG. 8A depicts an exemplary deposition pattern for metal layer 180 on the backside of a primary mirror array 200. The array 200 is masked along isolation lines 300, so that when metal layer 180 is deposited onto the array 200, two regions are formed. Inner region 310 is used for one polarity, while outer region 320 is used for a second polarity. Inner region 310 and outer region 320 may be composed of the same or different metals. An array 200 assembled with electrical packages 170 is depicted in FIG. 8B, showing the alignment of electrical contacts 172 with inner region 310. Consequently, electrical elements 172 have the same polarity as inner region 310, and electrical elements 174 have the polarity of outer region 320. The deposition pattern of FIGS. 8A and 8B form a parallel circuit for the electrical packages 170 and consequently their associated solar cells. Other patterns are possible for creating parallel or series circuits. Furthermore, a bypass diode may also be added on the backside of array 200. If a solar cell is faulty or otherwise fails to generate charge carriers, a bypass diode may electrically couple electrical elements 172 to electrical elements 174 in response to a received external signal.

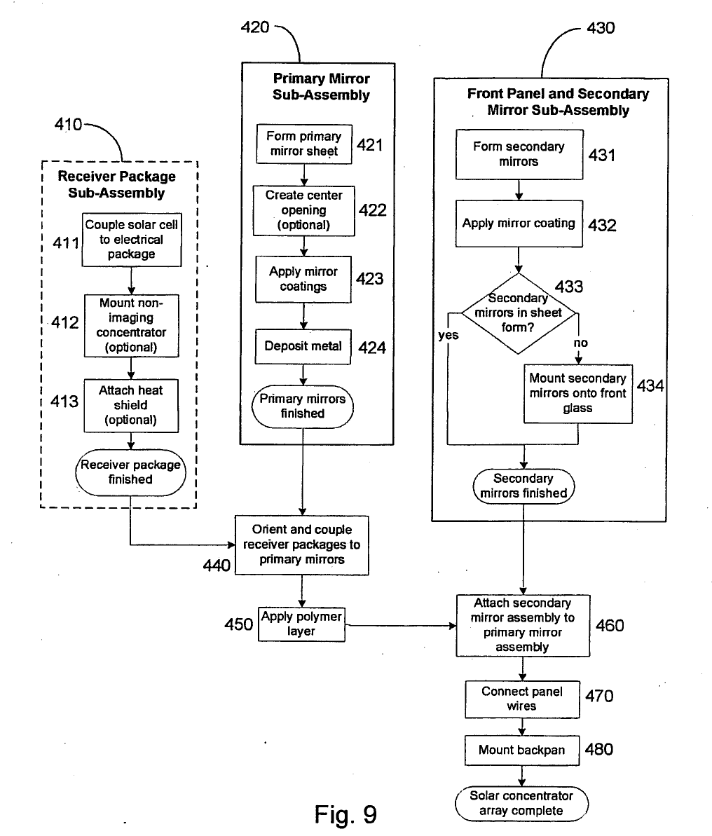

Fabrication of the solar concentrator of the present invention is exemplified in the basic flowchart 400 of FIG. 9. In this embodiment, three main sub-assemblies are utilized to construct a finished solar concentrator: a receiver package sub-assembly of block 410, a primary mirror sub-assembly of block 420, and a front panel and secondary mirror sub-assembly of block 430. In block 410, a receiver package sub-assembly begins by coupling a solar cell to an electrical package in step 411. Step 411 includes physically mounting the solar cell to the electrical package, as well as electrically connecting the solar cell to the electrical package using, for example, an electrically conductive adhesive. An optional non-imaging concentrator may be mounted to the electrical package in step 412, such as with an optical encapsulant, and an optional heat shield may also be attached to the electrical package in step 413.

Construction of a primary mirror sub-assembly in block 420 begins with forming a monolithic array of primary mirrors in step 421, for example by glass slumping. To achieve accurate slumping of the necessary size, such as sheets on the order of one square foot or more, the slumping mold used to form the primary mirrors may require vacuum ports both inside and outside of the mold cavities as described in co-pending U.S. patent application Ser. No. 12/044,939 entitled “Monolithic Glass Array.” Center openings may then be created in the primary mirrors in step 422, for example by cutting with water jets. Alternatively, center openings may not be required, such as in a configuration where the centers of the primary mirrors do not have mirror coatings applied and light is allowed to pass through to the solar cell. Next, the desired mirror layers, as described in relation to FIGS. 4A and 4B, are applied in step 423. Step 423 may include applying an insulating layer, such as a paint coating or polymer material. Step 424 involves depositing a metal layer, and may include masking to delineate metal layer regions to be used for opposite polarity. Deposition may be performed by methods known in the art, including but not limited to plasma vapor deposition, electrolytic plating, and thermal spraying.

The final sub-assembly, which includes a front panel and secondary mirrors, is formed in block 430. In step 431, secondary mirrors may be formed either as individual mirror pieces, or formed integrally with a front panel, for instance by slumping. As with the primary mirrors, integral forming of the secondary mirrors enables the secondary mirrors to be pre-aligned for mounting to the primary mirrors, and eliminates the step of joining them to the front panel. Secondary mirrors are coated with mirror layers in 432. In steps 433 and 434, if secondary mirrors are formed separately from the front panel, they are mounted onto the front panel. In one embodiment, secondary mirrors may be coupled to the front panel with adhesive using automated pick and place methods.

Once the sub-assemblies are complete in FIG. 9, the final solar concentrator array is assembled beginning in step 440 in which the receiver package sub-assemblies are coupled to the primary mirror sub-assembly. Note that because the primary mirrors are pre-aligned with each other, as well as potentially the secondary mirrors being integrally aligned in the front panel, the need to align individual solar concentrator units when assembling them into an array is eliminated. In step 440 the receiver packages are physically attached and electrically connected to the primary mirrors by appropriately orienting the electrical elements with the metal layer pattern, and attaching the receiver packages, such as with electrically conductive adhesive. In step 450, a polymer layer is applied over the metal layer on the backside of the primary mirrors, such as by spraying. The front panel with secondary mirrors is then placed over the front side of the primary mirror assembly in step 460. Finally, electrical panel wires for the overall array are electrically connected in step 470, and an optional backpan is mounted to enclose the assembly in step 480.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention. Thus, it is intended that the present subject matter covers such modifications and variations as come within the scope of the appended claims and their equivalents.

What is claimed is:

1. A solar concentrator array comprising:
an array of primary mirrors, wherein the array of primary mirrors is monolithically formed and has a backside;
a metal layer deposited on the backside of the array of primary mirrors;
a plurality of electrical packages electrically and thermally coupled to the metal layer;
a plurality of solar cells electrically coupled to the plurality of electrical packages; and
wherein the size of the primary mirrors is determined by the amount of heat to be dissipated by electrical packages and by the metal layer.

2. The solar concentrator array of claim 1, wherein each of the primary mirrors is substantially square.

3. The solar concentrator array of claim 2, wherein the sides of the primary mirrors measure between 30 to 300 millimeters in length.

4. The solar concentrator array of claim 1, wherein each of the primary mirrors is substantially hexagonal.

5. The solar concentrator array of claim 1, wherein each of the primary mirrors has a central opening and wherein one of the electrical packages are positioned over each of the central openings of the primary mirrors.

6. The solar concentrator array of claim 1, further comprising a plurality of non-imaging concentrators coupled to the plurality of solar cells.

7. The solar concentrator array of claim 1, wherein the each of the electrical packages comprises:
a first electrical element;
a second electrical element; and
a substrate, wherein the substrate electrically isolates the first electrical element from the second electrical element.

8. The solar concentrator array of claim 7, wherein each of the electrical packages comprises an aperture in the substrate.

9. The solar concentrator array of claim 1, wherein the metal layer substantially covers the backside of the array of primary mirrors.

10. The solar concentrator array of claim 1, wherein each of the primary mirrors has a depth, and wherein the size of the primary mirrors is further chosen according to the depth of the primary mirror to which the metal layer can be deposited with a desired thickness.

11. The solar concentrator array of claim 1, further comprising an array of secondary mirrors integrally formed with the front panel.

12. The solar concentrator array of claim 1, further comprising a polymer layer covering the metal layer.

13. The solar concentrator array of claim 1, further comprising a backpan covering the backside of the array of primary mirrors.

14. A method of fabricating a solar concentrator array, comprising:
forming a monolithic array of primary mirrors, wherein the monolithic array of primary mirrors has a backside;
depositing a metal layer onto the backside of the monolithic array of primary mirrors, wherein the size of the primary mirrors is determined by the amount of heat to be dissipated by the metal layer;
electrically and thermally coupling a plurality of electrical packages to the metal layer; and
coupling a plurality of solar cells to the plurality of electrical packages.

15. The method of fabricating a solar concentrator array of claim 14, wherein the primary mirrors are substantially squares having sides measuring between 30 to 300 millimeters in length.

16. The method of fabricating a solar concentrator array of claim 14, wherein each of the primary mirrors has a central opening, and wherein each of the electrical packages are positioned over each of the central openings of the primary mirrors.

17. The method of fabricating a solar concentrator array of claim 14, wherein each of the electrical packages comprises a first electrical element, a second electrical element, and a substrate isolating the first electrical element from the second electrical element.

18. The method of fabricating a solar concentrator array of claim 14, further comprising the step of coupling a plurality of non-imaging concentrators to the plurality of solar cells.

19. The method of fabricating a solar concentrator array of claim 14, wherein an array of secondary mirrors is coupled to the front panel.

20. The method of fabricating a solar concentrator array of claim 14, wherein the step of forming comprises a slumping process utilizing a slumping mold with mold cavities, and wherein the slumping mold has vacuum ports outside of the mold cavities.
